(19) United States
(12) Patent Application Publication
(10) Pub. No.: US 2013/0154442 A1
(43) Pub. Date: Jun. 20, 2013

(54) EXTERNAL FORCE DETECTION EQUIPMENT

(71) Applicant: NIHON DEMPA KOGYO CO., LTD., Tokyo (JP)

(72) Inventors: MITSUAKI KOYAMA, SAITAMA (JP); TAKERU MUTOH, SAITAMA (JP)

(73) Assignee: NIHON DEMPA KOGYO CO., LTD., TOKYO (JP)

(21) Appl. No.: 13/712,970

(22) Filed: Dec. 13, 2012

(30) Foreign Application Priority Data
Dec. 14, 2011 (JP) 2011-273775

(51) Int. Cl. H01L 41/113

(52) U.S. Cl. CPC H01L 41/1132
USPC 310/319

(57) ABSTRACT

To easily detect an external force applied to a piezoelectric element with high accuracy and suppress influence of electrostatic charges accumulated in the piezoelectric element. A crystal element is cantilevered inside the container. Excitation electrodes are formed on upper and lower faces, respectively, of the crystal element. A movable electrode connected to the excitation electrode is provided in a leading end portion of the lower face side of the crystal element, and a stationary electrode is provided in a bottom portion of the container. An oscillation loop including the excitation electrodes, the movable electrode, the stationary electrode, and the oscillator circuit is formed. A capacitance change between the electrodes caused by a deflection of the crystal element due to an external force is detected as a frequency. A switch for opening or closing the neutralization path to discharge electrostatic charges generated in the crystal element to the ground is provided.

### CROSS-REFERENCE TO RELATED APPLICATION

This application claims the priority benefit of Japanese application serial no. 2011-273775, filed on Dec. 14, 2011. The entirety of the above-mentioned patent application is hereby incorporated by reference herein and made a part of specification.

### BACKGROUND

1. Technical Field

The present invention relates to a technical field for detecting an external force such as acceleration, pressure, a flow velocity of fluid, a magnetic force, or an electrostatic force by detecting a magnitude of the external force applied to a piezoelectric element based on an oscillation frequency using a piezoelectric element such as a crystal element.

2. Description of the Related Art

An external force applied to a system includes a force applied to an object based on acceleration, pressure, a flow velocity, a magnetic force, an electrostatic force, and the like. There are many cases requiring accurate measurement of such an external force. For example, an impact force on a seat when a vehicle collides with an object is measured in a development process of a vehicle. In addition, there is a need to investigate acceleration of vibration as precisely as possible in order to study an amplitude or vibrational energy during an earthquake.

Furthermore, a measurement example of the external force may include a case where a flow velocity of liquid or gas is accurately measured, and a detection value thereof is reflected on a control system, or a case where performance of a magnet is measured. When such measurement is performed, it is necessary to provide a structure as simple as possible and high accuracy of measurement if possible.

In this regard, the inventors studied a technique of measuring an external force with high accuracy using a capacitance change based on a deflection generated when an external force is applied to a piezoelectric element. However, in some cases of the research process, there was a problem in that an electrostatic charge generated on the piezoelectric element due to static electricity causes an error in the measurement value under an environment, such as a dry winter season, in which static electricity is easily generated.

Japanese Unexamined Patent Application No. 2006-138852 (Patent Literature 1) discloses a technique in which a piezoelectric film is cantilevered and is deformed by a change of the ambient magnetic force so that the electric current flowing through the piezoelectric film varies. In addition, Japanese Unexamined Patent Application No. 2008-39626 (Patent Literature 2) discloses a technique in which a capacitive coupling type pressure sensor and a crystal resonator arranged in a space partitioned from the arrangement area of the pressure sensor are provided such that a variable capacitance of the pressure sensor is connected to the crystal resonator in parallel, and pressure is detected based on a change of the anti-resonance point of the crystal resonator caused by a change of the capacitance of a pressure sensor. These techniques are totally different from the present invention in principle.

[Patent Literature 1] Japanese Unexamined Patent Application No. 2006-138852, referring to paragraphs [0021] and [0028]

[Patent Literature 2] Japanese Unexamined Patent Application No. 2008-39626, referring to FIGS. 1 and 3

### SUMMARY

The present invention has been made in view of the aforementioned problems, and an aim thereof is to provide an external force detection equipment capable of easily detecting an external force applied to a piezoelectric element with high accuracy and preventing adverse effects of static electricity.

According to an aspect of the present invention, there is provided an external force detection equipment for detecting an external force applied to a piezoelectric element, including:

a piezoelectric element cantilevered onto a support portion in one end side;

a pair of excitation electrodes, one excitation electrode and the other excitation electrode being provided in one face side and the other face side, respectively, of the piezoelectric element to vibrate the piezoelectric element;

an oscillator circuit electrically connected to the one excitation electrode;

a movable electrode for forming a variable capacitance, the movable electrode being provided in a portion distant from the one end side of the piezoelectric element and electrically connected to the other excitation electrode;

a stationary electrode provided separately from the piezoelectric element and oppositely to the movable electrode and connected to the oscillator circuit so as to form a variable capacitance based on a capacitance change between the stationary electrode and the movable electrode caused by a deflection of the piezoelectric element;

a frequency information detection unit for detecting a signal as frequency information corresponding to an oscillation frequency of the oscillator circuit; and

a neutralization path for discharging a charge accumulated in the piezoelectric element to the ground by connecting the piezoelectric element to the ground,

wherein an oscillation loop including the oscillator circuit, the one excitation electrode, the other excitation electrode, the movable electrode, and the stationary electrode is formed, and the frequency information detected by the frequency information detection unit is used to evaluate a force applied to the piezoelectric element.

According to an embodiment of the present invention, a first switch may be provided in a conduction path of the oscillation loop so that an electric potential difference between the piezoelectric element and the stationary electrode becomes zero by turning on the first switch. In this configuration, a second switch is provided between the oscillator circuit and the power supply unit in order to prevent a short circuit between the oscillator circuit and a power supply unit during the use of the first switch.

According to another embodiment of the present invention, first and second groups are provided, each of the first and second groups including the piezoelectric element, the excitation electrodes, the movable electrode, and the stationary electrode, and the oscillator circuits are provided to match each of the first and second groups. The frequency information detection unit may have a configuration capable of obtaining a signal corresponding to a difference between an oscillation frequency of the first group and an oscillation frequency of the second group.

According to the present invention, based on a fact that a distance between the movable electrode in the piezoelectric element side and the stationary electrode opposite to the movable electrode varies when the piezoelectric element is bent, or its deflection varies as an external force is applied to the piezoelectric element so that a capacitance between both electrodes varies, this capacitance change is detected as a change of the oscillation frequency of the piezoelectric element. Therefore, since even slight deformation of the piezoelectric element can be detected as a change of the oscillation frequency, it is possible to measure an external force applied to the piezoelectric element with high accuracy. Furthermore, since a neutralization path for connecting the piezoelectric element to the ground is provided, it is possible to remove electrostatic charges accumulated in the piezoelectric element and prevent influence of an electrostatic force on the measurement result.

### BRIEF DESCRIPTION OF THE DRAWINGS

FIG. 1 is a longitudinal cross-sectional view illustrating a main part of the external force detection equipment applied as an acceleration sensing device according to a first embodiment of the present invention;

FIGS. 2A and 2B are plan views illustrating upper and lower faces, respectively, of the crystal element according to the first embodiment;

FIG. 3 is a block diagram illustrating a circuit configuration of the acceleration sensing device;

FIG. 4 is a circuit diagram illustrating the acceleration sensing device in detail;

FIGS. 5A and 5B are circuit diagrams illustrating an exemplary switch configuration according to the present invention;

FIG. 6 is a plan view illustrating an upper face of the crystal element in the acceleration sensing device according to a second embodiment;

FIG. 7 is a plan view illustrating an inner bottom portion of a container in the acceleration sensing device according to the second embodiment;

FIG. 8 is a plan view illustrating a back side of the crystal element according to the second embodiment;

FIG. 9 is a longitudinal cross-sectional view illustrating a situation that the crystal element is bent by an external force and dimensions of each part according to the second embodiment;

FIG. 10 is a block circuit diagram illustrating a circuit of the acceleration sensing device according to the second embodiment;

FIG. 11 is a circuit diagram illustrating an exemplary switch configuration according to the second embodiment; and

FIG. 12 is a plan view illustrating an upper face of the crystal element according to a third embodiment and a block circuit diagram illustrating connection to the oscillator circuit.

### DETAILED DESCRIPTION

### First Embodiment

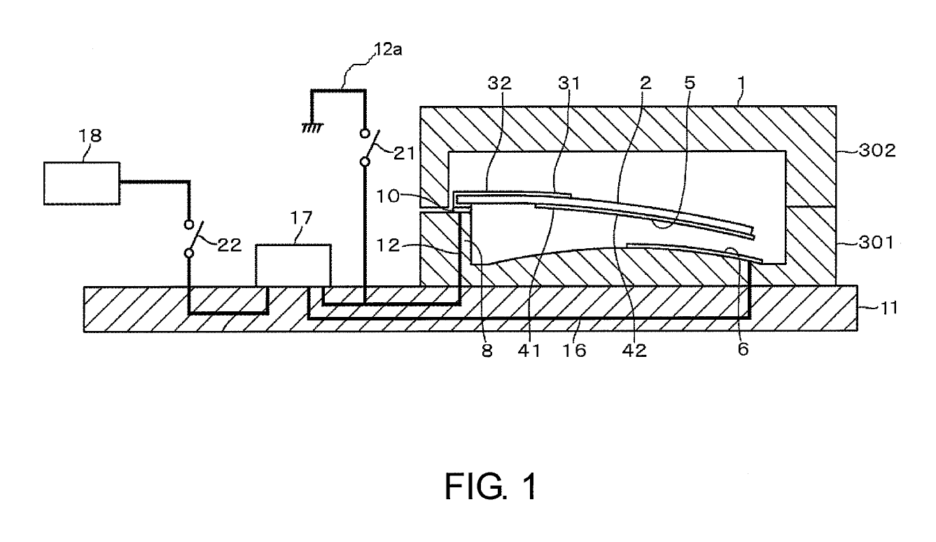

An acceleration sensing device according to the first embodiment of the present invention will be described. Referring to FIG. 1, the reference numeral 1 denotes an encapsulated rectangular container made of, for example, crystal and hermetically filled with inert gas such as nitrogen gas. This container 1 includes a lower portion 301 serving as a base and an upper portion 302 joining with a circumferential portion of the lower portion 301 and is provided on an insulating substrate 11. In addition, the container 1 is not necessarily limited to the encapsulated container. Inside the container 1, a pedestal portion 8 is provided, and one end side of the crystal element 2, which is a piezoelectric element, is fixed to the upper face of the pedestal portion 8 using a conductive adhesive 10. In this example, the pedestal portion 8 corresponds to a support portion for supporting the crystal element 2. That is, the crystal element 2 is cantilevered onto the pedestal portion 8. The crystal element 2 is obtained by forming, for example, X-cut crystal in a strip shape, and a thickness thereof is set to, for example, several micrometers (μm) order, such as 0.03 mm. Therefore, the leading end portion is bent by applying acceleration across the crystal element 2.

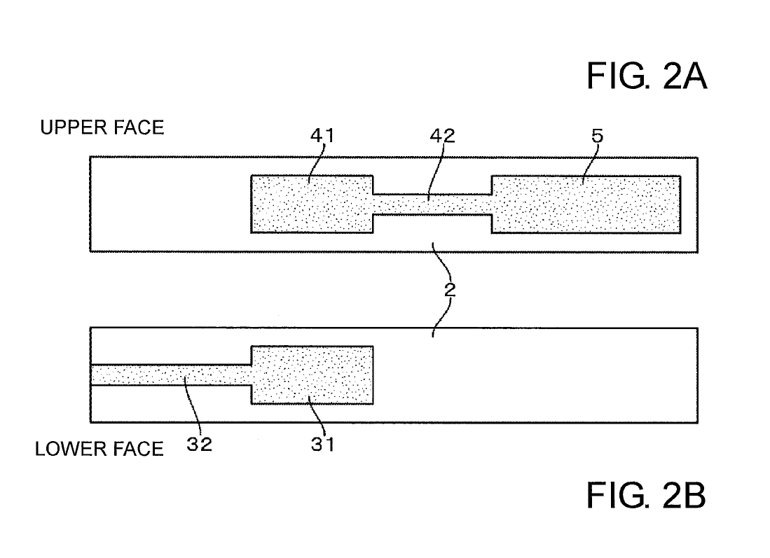

One excitation electrode 31 is provided in the center of the upper face of the crystal element 2 as illustrated in FIG. 2A, and the other excitation electrode 41 is provided in the area opposite to the one excitation electrode 31 on the lower face as illustrated in FIG. 2B, so as to provide a crystal resonator. A zonal extraction electrode 32 is connected to the excitation electrode 31 in the upper face side of the crystal element 2, and the extraction electrode 32 is bent down in one end side of the crystal element 2 and is fixed to the conductive adhesive 10. A conductive path 12 made of a metal layer is provided in the inside of the pedestal portion 8 and the insulating substrate 11. One end of the conductive path 12 makes contact with the conductive adhesive 10, and the other end is connected to the oscillator circuit 17 on the insulating substrate 11. In addition, a neutralization path 12a is branched from the middle of the conduction path 12 and is connected to the ground through a first switch 21.

A zonal extraction electrode 42 is connected to the excitation electrode 41 in the lower face side of the crystal element 2. This extraction electrode 42 is extracted to the other end side (leading end side) of the crystal element 2 and is connected to a movable electrode 5 for forming a variable capacitance. On the other hand, a stationary electrode 6 for forming a variable capacitance is provided in the side of the container 1. The bottom portion of the container 1 is provided with a convex protrusion 7 made of crystal. This protrusion 7 is rectangular as seen in a plan view. According to the present invention, an external force is detected based on a change of the capacitance between the movable electrode 5 and the stationary electrode 6 generated by deformation of the crystal element 2. Therefore, the movable electrode 5 may be called a detection electrode.

The stationary electrode 6 is provided to be substantially opposite to the movable electrode 5 in the protrusion 7. If the crystal element 2 excessively adjoins, and the leading end collides with the bottom portion of the container 1, a lump of the crystal may be easily defected due to cleavage. For this reason, the shape of the protrusion 7 is determined such that a region of the base end side (one end side) of the crystal element 2 rather than the movable electrode 5 collides with the protrusion 7 when the crystal element 2 excessively adjoins. The illustration of FIG. 1 is slightly different from that of an actual device. However, a region close to the center rather than the leading end of the crystal element 2 collides with the protrusion 7 if the container 1 is strongly vibrated in practice.

The stationary electrode 6 is connected to one end of the conduction path 16 wired through the insulating substrate 11, and the other end of the conduction path 16 is connected to the oscillator circuit 17. The oscillator circuit 17 is connected to a power supply unit 18 through the second switch 22. The first and second switches 21 and 22 may be arranged on the insulating substrate 11. Alternatively, the first and second switches 21 and 22 may be arranged in another place, for example, in a casing (not illustrated) used to store an assembly of the insulating substrate 11 and the container 1 illustrated in FIG. 1.

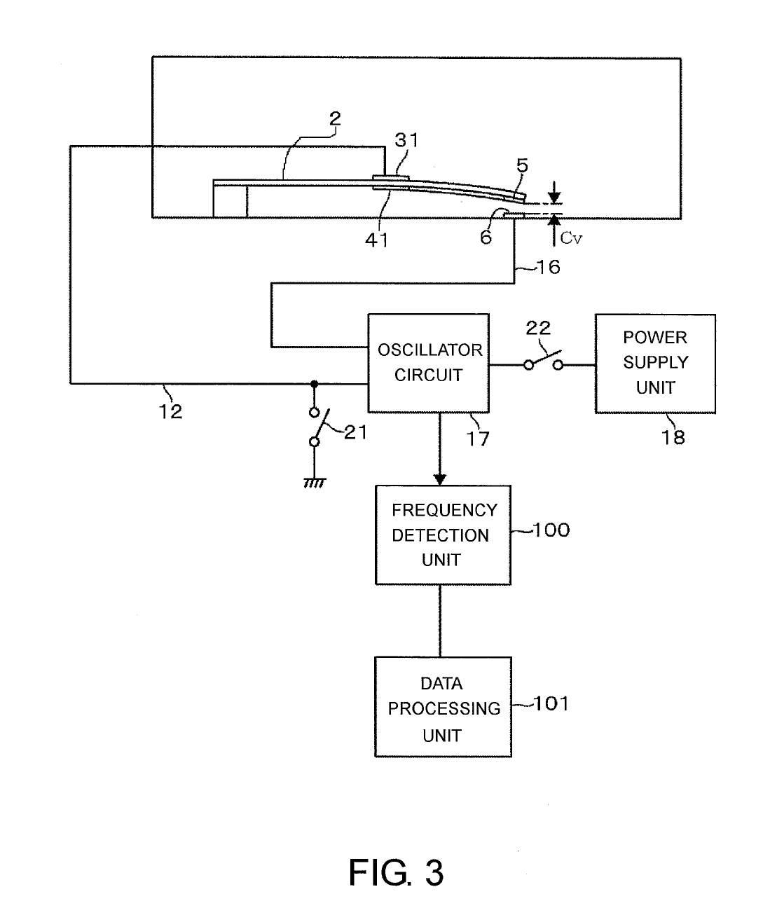

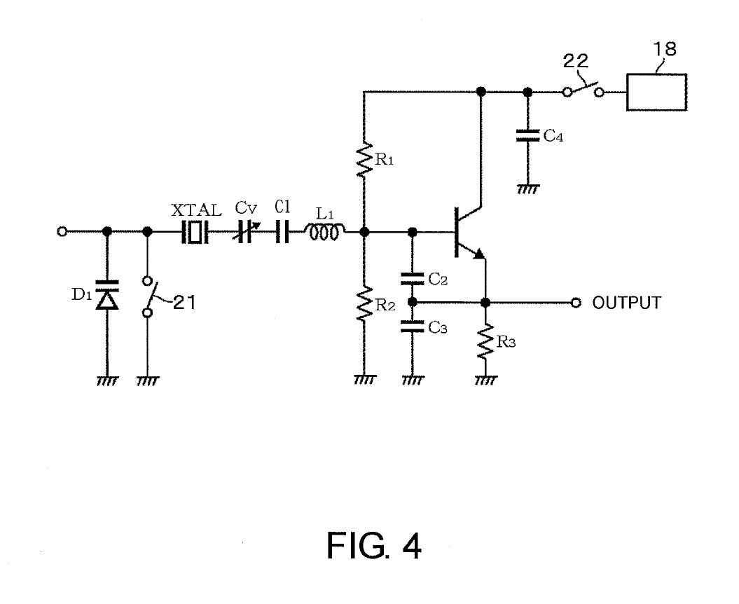

FIG. 3 illustrates a connection state of the wiring of the acceleration sensor, and FIG. 4 illustrates a circuit thereof in detail. The excitation electrode 31 of the upper face side and the excitation electrode 41 of the lower face side are connected to the oscillator circuit 17. A variable capacitance Cv formed between the movable electrode 5 and the stationary electrode 6 is interposed between the excitation electrode 41 of the lower face side and the oscillator circuit 17.

In FIG. 3, the reference numeral 101 denotes a data processing unit such as a personal computer. The data processing unit 101 has a following function, obtaining a difference between a frequency f0 detected when no acceleration is applied to the crystal element 2 and a frequency f1 detected when acceleration is applied based on frequency information such as frequencies obtained from the frequency detection unit 100, and obtaining the acceleration with reference to a data table indicating a relationship between the frequency change amount computed from this frequency difference and the acceleration. The frequency information is not limited to a change amount of the frequency difference and may include the frequency difference itself.

Here, according to the international standard IEC 60122-1, a general formula of the crystal oscillator circuit is expressed as the following equation (1):

FL=Fr×(1+x)

x=(C1/2)×1/(C0+CL) (1)

where FL denotes an oscillation frequency when a load is applied to the crystal resonator, and Fr denotes an resonant frequency of the crystal resonator of itself.

In this embodiment, as illustrated in FIGS. 3 and 4, a load capacitance of the crystal element 2 is obtained by adding Cv to CL. Therefore, the term y expressed in the equation (2) is substituted with CL in the equation (1).

y=1/(1/Cv+1/CL) (2)

Therefore, assuming that a deflection of the crystal element 2 is changed from the state 1 to the state 2, and the variable capacitance Cv is changed from Cv1 to Cv2, the frequency change dFL is expressed as the following equation (3).

dFL=FL1−FL2=A×CL²×(Cv2−Cv1)/(B×C) (3)

where A=C1×Fr/2

B=C0×CL+(C0+CL)×Cv1

C=C0×CL+(C0+CL)×Cv2

In addition, if a distance between the movable electrode 5 and the stationary electrode 6 when no acceleration is applied to the crystal element 2 (so-called reference state) is denoted by d1, and the distance when acceleration is applied to the crystal element 2 is denoted by d2, the following equation (4) is established.

Cv1=S×ε/d1

Cv2=S×ε/d2 (4)

where S denotes an area of the opposing region between the movable electrode 5 and the stationary electrode 6, and ε denotes a relative dielectric constant.

Since the distance d1 is known, it is recognized that there is a matching relationship between dFL and d2.

Next, effects of the aforementioned embodiment will be described. In some cases, the crystal element 2 is bent, for example, such that the movable electrode 5 approaches the stationary electrode 6 due to an electrostatic force between the container 1 and the crystal element 2 generated by the electrostatic charges accumulated under an environment, such as a dry winter season, in which static electricity is easily generated. At this time, a deflection of the crystal element 2 is about one degree, for example.

If the measurement is performed in this state, an error may occur in the measurement result. If a deflection of the crystal element 2 is significant, the movable electrode 5 and the stationary electrode 6 may make contact with each other so as to cause an unmeasurable state.

In this regard, the first switch 21 is turned on before the second switch 22 is turned on (before power is supplied). As a result, a neutralization path is formed between the crystal element 2 and the ground, so that electrostatic charges accumulated in the crystal element 2 are discharged to the ground. In addition, the crystal element 2 is avoided from the electrostatic attraction and is recovered to a predetermined position, so that it is possible to obtain a state where the accurate measurement can be performed. Then, the first switch 21 is returned to the off-state, and subsequently, the second switch 22 is turned on, so as to prepare acceleration detection.

In addition, if an earthquake is generated, or simulative vibration is applied, the crystal element 2 is bent as indicated in a chain line of FIG. 1 or a solid line of FIG. 3. Assuming that a capacitance between the movable electrode 5 and the stationary electrode 6 in a reference state where an external force is not applied to the crystal element 2 is denoted by Cv1, the capacitance varies from Cv1 because the distance between both electrodes 5 and 6 varies as the crystal element 2 is bent due to an external force applied to the crystal element 2. For this reason, the oscillation frequency output from the oscillator circuit 14 varies.

Assuming that the frequency detected by the frequency detection unit 100, which is a frequency information detection unit, when no vibration is applied is denoted by FL1, and the frequency detected when vibration (acceleration) is applied is denoted by FL2, a frequency difference (FL1−FL2) is expressed as the equation (3). The inventors computed a frequency change rate obtained when the state 1 is changed to the state 2 based on the frequency difference (FL1−FL2) and investigated a relationship between the frequency change rate (FL1−FL2)/FL1 and the acceleration. As a result, a linear relationship was obtained. Therefore, it was proved that the acceleration is obtained by measuring the frequency difference. In addition, the value of FL1 refers to a frequency value at a reference temperature of, for example, 25° C. determined arbitrarily.

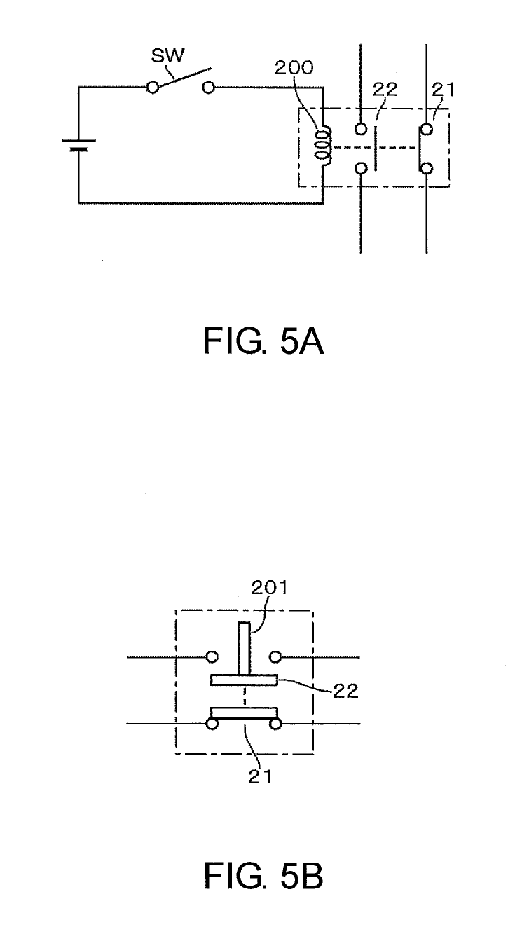

Subsequently, exemplary first and second switches 21 and 22 are illustrated in FIG. 5A. In this example, the first and second switches 21 and 22 are opened and closed when electricity flows respectively and are integrated into a relay circuit. The first switch 21 is turned on, and the second switch 22 is turned off since electricity does not flow to the relay coil 200 while the main switch SW is turned off.

As the main switch SW is turned on, electricity flows to the relay coil 200 so that the first switch 21 is turned off, and the second switch 22 is turned on. Therefore, in this example, it is possible to reliably perform neutralization while power is not supplied to the oscillator circuit 17.

The first and second switches 21 and 22 may be configured as linked switches such that the first and second switches 21 and 22 have an ON-OFF state or an OFF-ON state by controlling the operational unit 201 as illustrated in FIG. 5B.

Here, description will be made for an inspection example in which the crystal element 2 is electrically charged. A DC voltage of 2 kV was applied to the crystal element 2 for 10 seconds before the oscillator circuit 17 is operated using the device of FIG. 1. As a result, a parallel capacitance C0 of the crystal resonator was 2.15 pF. After 5 minutes from that time, the second switch 22 of the power supply of the oscillator circuit 17 was turned on (while the first switch 21 is turned off) for 30 seconds, and then, the second and first switches 22 and 21 were set to the OFF-ON state. As a result, the parallel capacitance C0 of the crystal resonator was 2.26 pF. It is supposed that this change results from the deflection of the crystal element 2 caused by static electricity. In addition, the Fr of the crystal resonator was 73.832294 MHz, the Rr was 6.9 ohm, the CL was 9.665 F.

### Second Embodiment

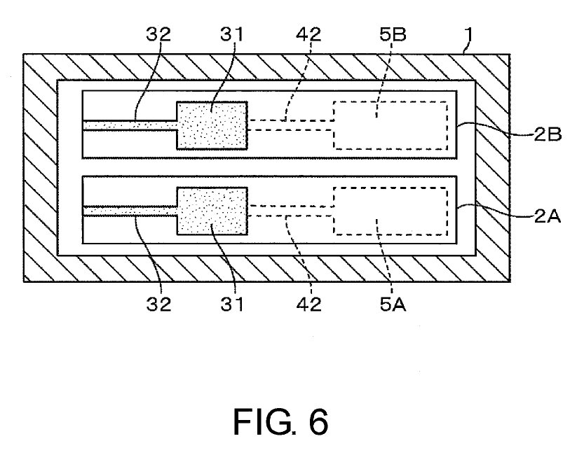

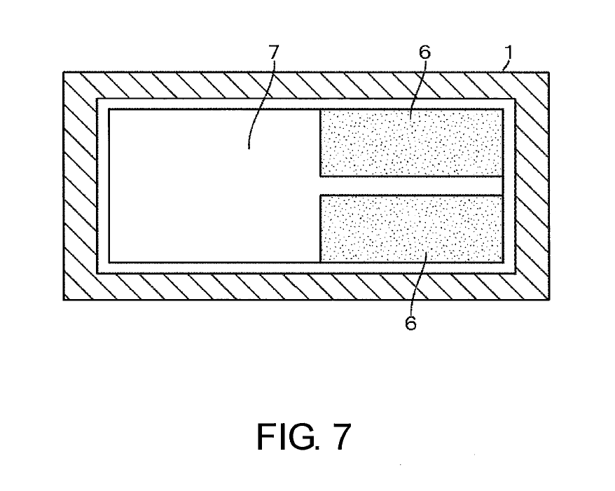

Next, the second embodiment of the present invention will be described with reference to FIGS. 6 to 11, in which the present invention is applied to an acceleration sensor. The second embodiment is different from the first embodiment in that a pair of groups are provided, each group including the crystal element 2, the excitation electrodes 31 and 41, the movable electrode 5, the stationary electrode 6, and the oscillator circuit 17 described above. For the crystal element 2 and the oscillator circuit 17, a reference symbol A is appended to the components of one group, and a reference symbol B is appended to the components of the other group. If the inside of the pressure sensor is seen in a plan view, the first and second crystal elements 2A and 2B are arranged horizontally in parallel as illustrated in FIG. 6.

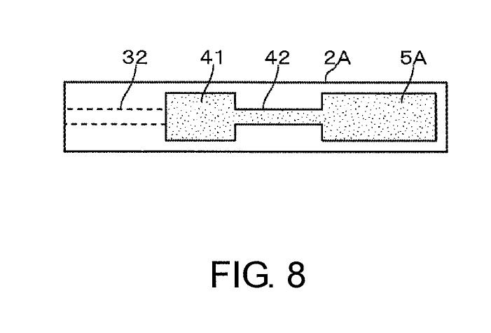

Since the crystal elements 2A and 2B have the same structure, only one of the crystal elements 2A will be described. A narrow-width extraction electrode 32 extends from one end side to the other end side on one face (upper face) of the crystal element 2A, and one excitation electrode 31 is formed in a rectangular shape in the leading end portion of the extraction electrode 32. In addition, as illustrated in FIG. 8, the other excitation electrode 41 is formed oppositely to the one excitation electrode 31 on the other face (lower face) of the crystal element 2A, and a narrow-width extraction electrode 42 extends to the leading end side of the crystal element 2 in the excitation electrode 41. Furthermore, a movable electrode 5A having a strip shape for generating a variable capacitance is formed in the leading end side of the extraction electrode 42. Theses electrodes and the like are formed of a conductive film such as a metal film.

A convex protrusion 7 made of crystal is provided in the bottom portion of the container 1 as illustrated in FIG. 1. However, the horizontal width of the protrusion 7 is set to a size corresponding to the arrangement of a pair of crystal elements 2A and 2B.

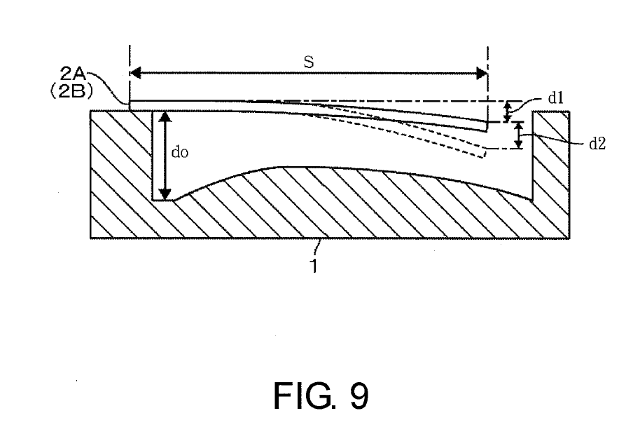

Description will be made for exemplary dimensions of each part in the crystal element 2A (2B) and peripherals thereof with reference to FIG. 9. The length S and the width of the crystal element 2A (2B) are set to 18 mm and 3 mm, respectively. The thickness of the crystal element 2A (2B) is set to, for example, several micrometers. Assuming that the support face in one end side of the crystal element 2A (2B) is set in parallel with a horizontal plane, the crystal element 2A (2B) is bent due to its own weight while it is left alone without acceleration. The deflection d1 thereof is, for example, 150 μm. The depth d0 of the concave space in the lower portion of the container 1 is, for example, 175 μm. In addition, the height of the protrusion 7 is, for example, 55 μm to 60 μm. Such dimensions are just exemplary.

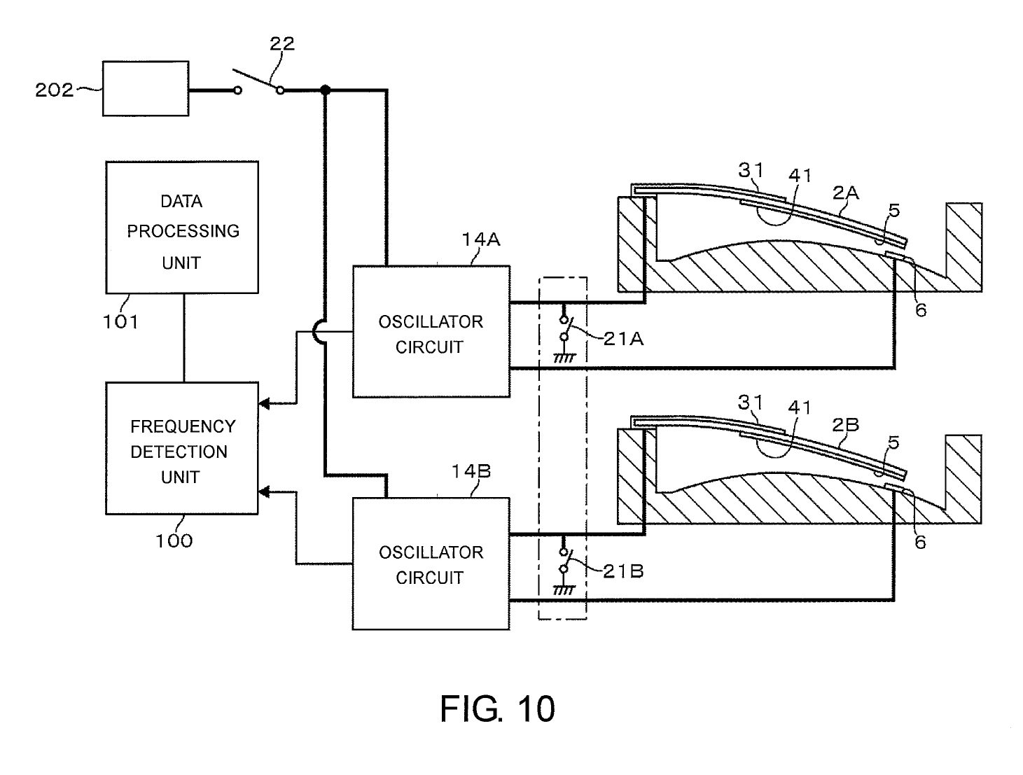

FIG. 10 illustrates a circuit of the acceleration sensing device according to the second embodiment. The second embodiment is different from the first embodiment in that the first oscillator circuit 14A and second oscillator circuit 14B are connected to match the first and second crystal elements 2A and 2B, respectively, and an oscillation loop including the oscillator circuit 14A (14B), the excitation electrodes 31 and 41, the movable electrode 5A (5B), and the stationary electrode 6 is formed for each of the first and second crystal elements 2A and 2B. The output of the oscillator circuit 14A or 14B is transmitted to the frequency detection unit 100, where a difference between the oscillation frequencies from each oscillator circuit 14A and 14B or a difference of the frequency change rate is detected.

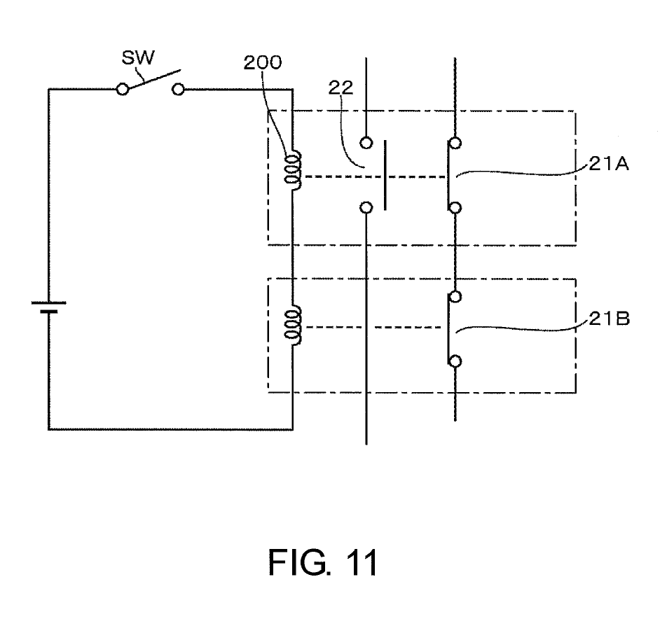

In FIG. 10, neutralization switches 21A and 21B are provided to match the first and second crystal elements 2A and 2B, respectively. In addition, a second switch 22, which is used for putting a common power, is provided for supplying a voltage from a common power supply 202 to the first and second oscillator circuits 14A and 14B. The neutralization switches 21A and 21B are turned on during the nonuse time in order to prevent the crystal elements 2A and 2B from being electrically charged. The neutralization switches 21A and 21B are turned off, and the second switch 22 is turned on during the use time. The switches 21A, 21B, and 22 may be configured as a relay circuit. In this case, when the main switch SW is turned off, the neutralization switches 21A and 21B are turned on, and the second switch 22 is turned off. When the main switch SW is turned on, the neutralization switches 21A and 21B are turned off, and the second switch 22 is turned on. An exemplary circuit diagram for realizing such operation is illustrated in FIG. 11. FIG. 11 illustrates application of the circuit of the circuit diagram of FIG. 5.

According to the second embodiment, the crystal elements 2A and 2B are arranged under the same temperature environment. Therefore, even when each of the frequencies of the crystal elements 2A and 2B varies due to a temperature change, this variation is cancelled. As a result, since a frequency change amount can be detected only based on the deflection of the crystal elements 2A and 2B, it is possible to obtain high detection accuracy. Furthermore, similar to the device according to the first embodiment, the device according to the second embodiment has a mechanism for easily removing the electrostatic charges accumulated in the piezoelectric element through switch operation. Therefore, it is possible to prevent an error in the measurement result caused by electrostatic attraction.

### Third Embodiment

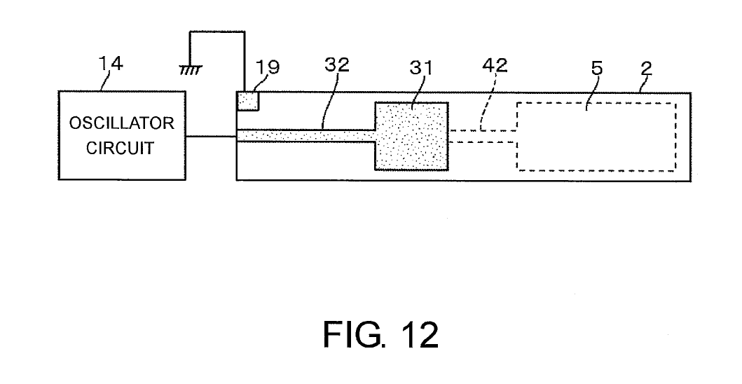

In the third embodiment, a dedicated neutralization electrode is provided in the crystal element 2, and the crystal element 2 is connected to the ground at all times. FIG. 12 illustrates an exemplary device according to the third embodiment.

The dedicated neutralization electrode 19 is provided in a portion on the crystal element 2, separated from the excitation electrodes 31 and 41, and the movable electrode 5, and is connected to the ground at all times. Since the dedicated neutralization electrode 19 is not electrically connected to the excitation electrodes 31 and 41 and the movable electrode 5, the electrostatic charge itself on the crystal element 2 are discharged to the ground even while the device is operated. Therefore, it is possible to obtain the same effects as those of the methods described above in the first and second embodiments, in which the electrostatic charges of the crystal element 2 are discharged to the ground using the switches 21 and 22. The third embodiment can be applied to the acceleration sensing device according to the first embodiment and the acceleration sensor according to the second embodiment. As an advantage of the third embodiment, it is possible to easily discharge the accumulated electrostatic charges without necessity of means for turning on and off the switch and perform accurate measurement.

Although the prevent invention has been described hereinbefore, it is not limited to the measurement of acceleration. The present invention may also be applied to measurement of a magnetic force, inclination of a measurement target, a fluid flow amount, a wind velocity, gravity, and the like.

What is claimed is:

1. An external force detection equipment for detecting an external force applied to a piezoelectric element, comprising:
a piezoelectric element, cantilevered onto a support portion in one end side;
a pair of excitation electrodes, one excitation electrode and the other excitation electrode being provided in one face side and the other face side, respectively, of the piezoelectric element to vibrate the piezoelectric element;
an oscillator circuit, electrically connected to the one excitation electrode;
a movable electrode, for forming a variable capacitance, the movable electrode being provided in a portion distant from the one end side of the piezoelectric element and electrically connected to the other excitation electrode;
a stationary electrode, provided separately from the piezoelectric element and oppositely to the movable electrode and connected to the oscillator circuit so as to form a variable capacitance based on a capacitance change between the stationary electrode and the movable electrode caused by a deflection of the piezoelectric element;
a frequency information detection unit, for detecting a signal as frequency information corresponding to an oscillation frequency of the oscillator circuit; and
a neutralization path, for discharging an electrostatic charge generated in the piezoelectric element to the ground by connecting the piezoelectric element to the ground,
wherein an oscillation loop including the oscillator circuit, the one excitation electrode, the other excitation electrode, the movable electrode, and the stationary electrode is formed, and
the frequency information detected by the frequency information detection unit is used to evaluate a force applied to the piezoelectric element.

2. The external force detection equipment according to claim 1, further comprising:
a neutralization switch, for opening or closing the neutralization path.

3. The external force detection equipment according to claim 2, further comprising:
a power switch, for connecting the oscillator circuit to a power supply unit,
wherein, the neutralization switch is turned on when the power switch is turned off, and the neutralization switch is turned off when the power switch is turned on.
